(19) United States
(12) Patent Application Publication
(10) Pub. No.: US 2020/0232091 A1
(43) Pub. Date: Jul. 23, 2020

(54) MASK FRAME ASSEMBLY AND MANUFACTURING METHOD THEREOF

(71) Applicant: SAMSUNG DISPLAY CO., LTD., Yongin-si (KR)

(72) Inventors: Junghyun AHN, Yongin-si (KR); Jaesuk Dustin MOON, Yongin-si (KR); Seungjin LEE, Yongin-si (KR)

(21) Appl. No.: 16/541,495

(22) Filed: Aug. 15, 2019

(30) Foreign Application Priority Data
Jan. 21, 2019 (KR) 10-2019-0007582

(51) Int. Cl. C23C 16/04; H01L 51/56

(52) U.S. Cl. CPC C23C 16/042; H01L 51/0011; H01L 51/56

(57) ABSTRACT

A mask frame assembly includes a frame, a mask combined to the frame and including a pattern area for deposition on a substrate, and a long-side stick combined to the frame and dividing the pattern area of the mask into unit cell patterns. The long-side stick may include a clad structure in which a relatively ferromagnetic layer and a relatively weak magnetic layer are stacked.

### CROSS-REFERENCE TO RELATED APPLICATION

Korean Patent Application No. 10-2019-0007582, filed on Jan. 21, 2019, in the Korean Intellectual Property Office, and entitled: “Mask Frame Assembly and Manufacturing Method Thereof,” is incorporated by reference herein in its entirety.

### BACKGROUND

### 1. Field

Embodiments relate to a mask frame assembly used for a deposition process and a method of manufacturing the mask frame assembly.

### 2. Description of the. Related Art

Generally, an organic light-emitting display device may implement colors according to a principle by which holes and electrons injected from an anode and a cathode recombine in an emission layer and emit light. Pixels each have a stack structure in which an emission layer is between a pixel electrode, which is an anode, and an opposite electrode, which is a cathode.

Each of the pixels may be one of a red sub-pixel, a green sub-pixel, and a blue sub-pixel, and a target color may be expressed by combination of the three color sub-pixels. Thus, in each sub-pixel, an emission layer emitting one of red, green, and blue light is located between two electrodes, and color of a pixel unit is expressed by an appropriate combination of the three color lights.

### SUMMARY

Embodiments are directed to a mask frame assembly, including a frame, a mask combined to the frame and including a pattern area for deposition on a substrate, and a long-side stick combined to the frame and dividing the pattern area of the mask into unit cell patterns. The long-side stick may include a clad structure in which a relatively ferromagnetic layer and a relatively weak magnetic layer are stacked.

A thickness of the relatively ferromagnetic layer may be greater than a thickness of the relatively weak magnetic layer in a stacking direction.

A protrusion protruding in a width direction may be located at the relatively weak magnetic layer.

The protrusion may correspond to a non-emission pattern at a side of the unit cell pattern.

The protrusion may include a semicircular shape.

A plurality of the protrusions may be periodically arranged in a length direction at an end portion of the relatively weak magnetic layer in a width direction.

The clad structure may include a structure in which the relatively weak magnetic layer is located between a pair of the relatively ferromagnetic layers.

The relatively ferromagnetic layer may be an iron-nickel alloy layer, and the relatively weak magnetic layer may be a stainless steel layer.

The long-side stick may bring the mask into close contact with the substrate when a magnetic force is applied to the long-side stick from a position opposite to the long-side stick, with the mask and the substrate therebetween.

A contact force applied to the mask by the long-side stick may be a combination of relatively strong attraction of the relatively ferromagnetic layer and relatively weak attraction of the relatively weak magnetic layer.

Embodiments are also directed to a method of manufacturing a mask frame assembly, the method including preparing a long-side stick having a clad structure in which a relatively ferromagnetic layer and a relatively weak magnetic layer are stacked, fixing the long-side stick to a frame, and fixing, to the frame, a mask having a pattern area to be divided by the long-side stick.

The method may further include forming the relatively ferromagnetic layer of the long-side stick to have a thickness greater than a thickness of the relatively weak magnetic layer in a stacking direction.

The method may further include forming, at the relatively weak magnetic layer, a protrusion protruding in a width direction.

The protrusion may correspond to a non-emission pattern at a side of a unit cell pattern.

The protrusion may include a semicircular shape.

The method may further include periodically arranging a plurality of the protrusions in a length direction at an end portion of the relatively weak magnetic layer in a width direction.

The clad structure may have a structure in which the relatively weak magnetic layer is located between a pair of the relatively ferromagnetic layers.

The relatively ferromagnetic layer may be an iron-nickel alloy layer, and the relatively weak magnetic layer may be a stainless steel layer.

The long-side stick may bring the mask into close contact with a substrate when a magnetic force is applied to the long-side stick from a position opposite to the long-side stick, with the mask and the substrate therebetween.

A contact force applied to the mask by the long-side stick may be a combination of relatively strong attraction of the relatively ferromagnetic layer and relatively weak attraction of the relatively weak magnetic layer.

### BRIEF DESCRIPTION OF THE DRAWINGS

Features will become apparent to those of skill in the art by describing in detail example embodiments with reference to the attached drawings in which:

FIG. 1 illustrates a deposition process in which a mask frame assembly according to an example embodiment is used;

FIG. 2 illustrates a disassembled perspective view of the mask frame assembly shown in FIG. 1;

FIG. 3 illustrates a top-plan view of the mask frame assembly shown in FIG. 1;

FIG. 4 illustrates an enlarged perspective view of region A shown in FIG. 2;

FIGS. 5A through 5C are cross-sectional views sequentially illustrating a process of manufacturing a long-side stick in the mask frame assembly shown in FIG. 1; and

FIG. 6 illustrates a cross-sectional view of a detailed structure of a target substrate shown in FIG. 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

In the following embodiments, an expression used in the singular encompasses the expression of the plural, unless it has a clearly different meaning in the context.

In the following embodiments, the terms such as “including,” “having,” and “comprising” are intended to indicate the existence of features or components disclosed in the specification, and are not intended to preclude the possibility that one or more other features or components may be added.

When a certain embodiment may be implemented differently, a specific process order may be performed differently from the described order. For example, two consecutively described process may be performed substantially at the same time or performed in an order opposite to the described order.

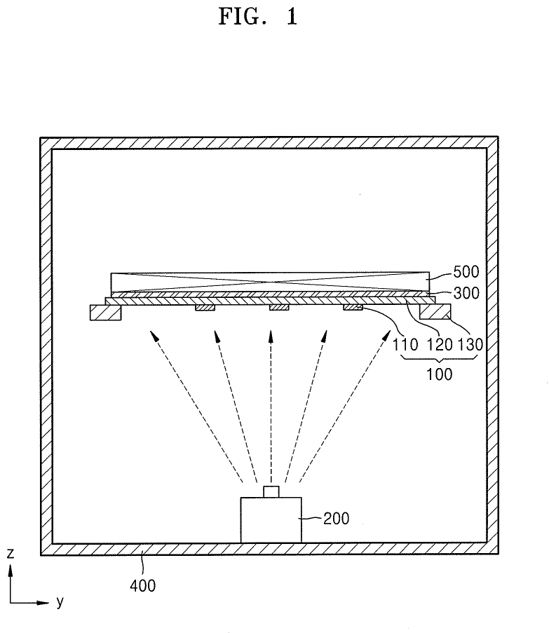

FIG. 1 is a schematic diagram of a structure of a thin film deposition apparatus employing a mask frame assembly 100 according to an example embodiment.

As shown in FIG. 1, the thin film deposition apparatus is provided with the mask frame assembly 100 for forming a desired pattern on a target substrate 300, and a deposition source 200 for jetting deposition gas toward the target substrate 300 in a chamber 400.

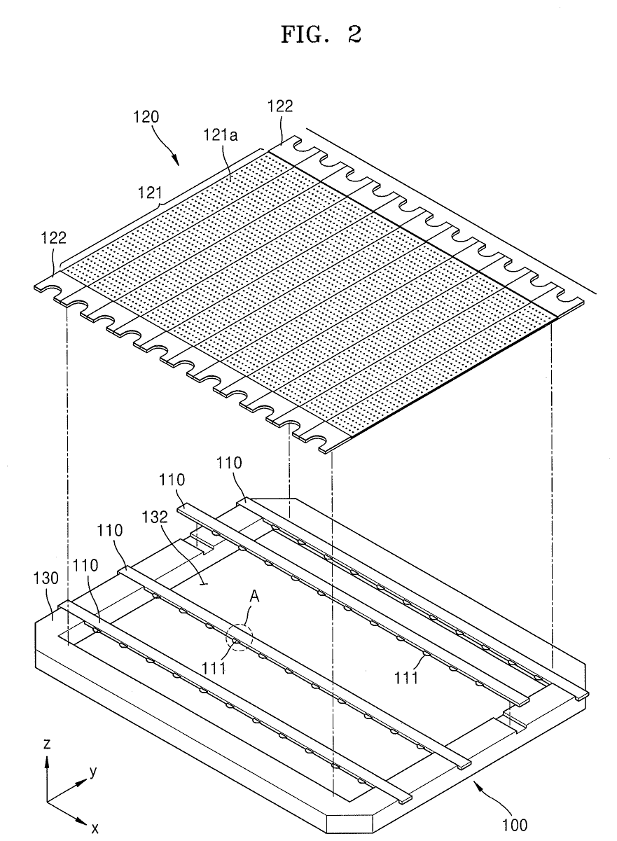

When the deposition source 200 jets deposition gas in the chamber 400, the deposition gas passes through pattern holes 121a (see FIG. 2) formed in a mask 120 of the mask frame assembly 100 and adheres to the target substrate 300, thereby forming a thin film having a pattern. Reference number 500 denotes a magnet that applies a magnetic force to the mask 120 such that the mask 120 is brought into close contact with the target substrate 300.

According to the present example embodiment, the mask frame assembly 100 includes the mask 120 in which the pattern holes 121a are formed as shown in FIG. 2, a frame 130 supporting two ends of the mask 120, and a long-side stick 110 that is supported by the frame 130 and perpendicularly crosses the mask 120.

According to the present example embodiment, the frame 130, which forms an outer frame of the mask frame assembly 100, has a square shape with an opening 132 formed in the middle. Two opposite ends of the long-side stick 110 in a length direction (the X direction) are respectively fixed, for example, by welding, to a pair of sides of the frame 130 that face each other, and two opposite ends of the mask 120 in a length direction (the Y direction) are fixed, for example, by welding, to a pair of sides perpendicular to the sides to which the long-side stick 110 is welded.

According to the present example embodiment, the mask 120 includes a plurality of long stick-shaped members, and a plurality of pattern holes 121a are formed in a pattern area 121 located in the opening 132, and the two opposite ends of the mask 120 are welded to the frame 130 as described above. Reference number 122 denotes a support portion. When welding the mask 120 to the frame 130, welding may be performed by holding the support portion 122 and tensioning the support portion 122 in a length direction, and after completing the welding, portions protruding outside the frame 130 may be removed by cutting. The mask 120 may be formed of a plurality of stick shapes that are divided as shown in FIG. 2, as, if the mask 120 is formed into one large element, severe deflection may occur due to self-load. The mask 120 may include Invar which is an iron-nickel alloy.

The pattern holes 121a are holes through which deposition vapor passes in a deposition process, and the deposition vapor passing through the pattern holes 121a adheres to the target substrate 300 (see FIG. 1) and forms a thin film layer.

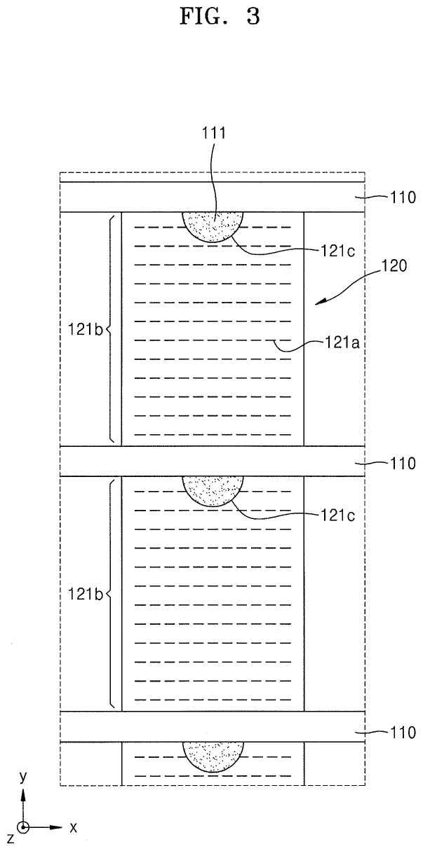

According to the present example embodiment, the pattern area 121 is connected in a great length instead of being divided into cell units having constant intervals, and the long-side stick 110 divides the pattern area 121 into cell units. Thus, as shown, the mask 120 and the long-side stick 110 are mounted to be in close contact with each other by perpendicularly crossing the frame 130. Accordingly, the long-side stick 110 crosses the pattern area 121 of each portion of the mask 120 and divides the pattern area 121 into cell units. Thus, the long-side stick 110 draws boundary lines between the unit cells. FIG. 3 is a top-plan view of the pattern area 121 divided into cell unit patterns 121b by the long-side stick 110. As described above, the pattern area 121 is divided into a plurality of unit cell patterns 121b by the long-side stick 110. In addition, a notch portion 121c that is a non-emission pattern of a non-linear type may be included in each of the unit cell patterns 121b. Accordingly, a protrusion 111 covering the notch portion 121c to prevent deposition of a thin film for emission on the notch portion 121c may be provided on the long-side stick 110.

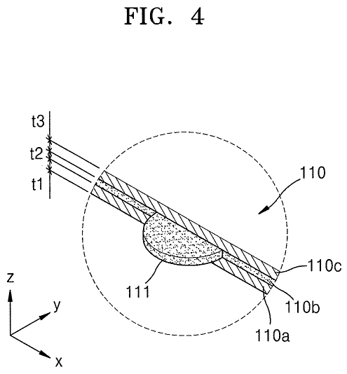

As shown in FIG. 4, according to the present example embodiment, the long-side stick 110 has a clad structure in which a plurality of metal layers are stacked.

Thus, according to the present example embodiment, the long-side stick 110 has a sandwich-type stack structure in which a second layer 110b, which is relatively weakly magnetic, is located between a first layer 110a and a third layer 110c that are relatively ferromagnetic. The first layer 110a and the third layer 110c may be or include Invar, which is an iron-nickel alloy, and the second layer 110b between the first layer 110a and the third layer 110c may be or include stainless steel.

According to the present example embodiment, the long-side stick 110 has the clad structure in which the first layer 110a and the third layer 110c, which are relatively ferromagnetic layers, and the second layer 110b, which is a relatively weak magnetic layer, are stacked, such that the contact force applied to the mask 120 is maintained at an adequate level that is neither excessively strong nor excessively weak.

If the entire portion of the long-side stick 110 were to include Invar (which is a ferromagnetic layer) when magnetic force of the magnet 500 (see FIG. 1) is applied to the mask frame assembly 100, force of the long-side stick 110 that presses the mask 120 toward the target substrate 300 could be excessively strong, such that the pattern holes 121a of the mask 120 could be deformed due to the excessive force of the long side stick 110. Thus, an icicle defect could occur whereby a large gap could be formed between the mask 120 and the target substrate 300, and excessive deposition could occur in the gap.

On the other hand, if the entire portion of the long-side stick 110 were to include stainless steel (which is a weak magnetic layer), the force of the long-side stick 110 to press the mask 120 toward the target substrate 300 could be too weak, such that a shadow defect could occur in which the mask 120 and the target substrate 300 do not properly adhere to each other and have a gap therebetween. Thus, deposition could occur beyond a periphery of an intended deposition area.

Therefore, in the present example embodiment, the long-side stick 110 is formed into the clad structure in which the first layer 110a and the third layer 110c, which are the ferromagnetic layers, and the second layer 110b, which is the weak magnetic layer, are stacked. Thus, an adequate level of contact force may be implemented by combination of ferromagnetism and weak magnetism.

Furthermore, in the present example embodiment, as shown in FIG. 4, thicknesses t1 and t3 of the first layer 110a and the third layer 110c, which are the ferromagnetic layers, are set to be greater than a thickness t2 of the second layer 110b that is the weak magnetic layer. Thus, by including the second layer 110b that is the weak magnetic layer, the contact force may be weakened compared to a case in which the long-side stick 110 only includes the ferromagnetic layers, but on the other hand a weak magnetic layer is not used as a main layer since an excessively weakened contact may cause a shadow defect.

In the present example embodiment, the protrusion 111, which is used for forming the notch portion 121c of the unit cell pattern 121b, is formed in the second layer 110b that is the weak magnetic layer. The presence of the protrusion 111 increases an area that is drawn by the magnet 500 by an amount that corresponds to the area of the protrusion 111. Accordingly, when the protrusion 111 is formed at the first layer 110a and the third layer 110c that are the ferromagnetic layers, the contact force that has decreased due to the second layer 110b that is the weak magnetic layer may be immediately offset or may even increase. Therefore, the protrusion 111 is formed at the weak magnetic layer in which an increase in the contact force due to an increase in an area is relatively small, that is, at the second layer 110b including stainless steel.

The long-side stick 110 having the clad structure as described above may be manufactured in press and etching processes. A detailed manufacturing process of the mask frame assembly 100 including the long-side stick 110 is described below.

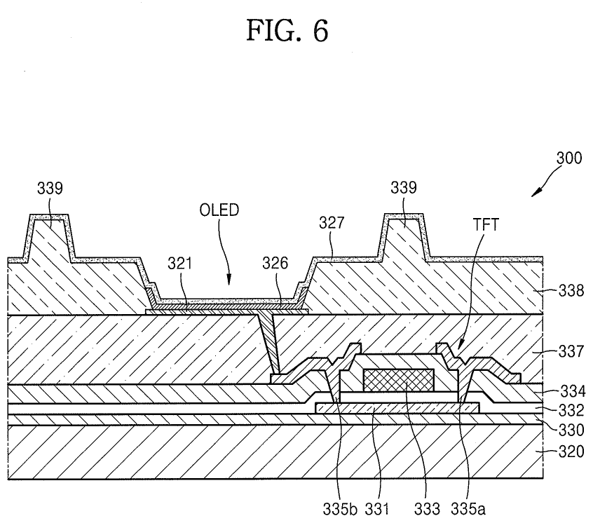

An example of the target substrate 300 on which deposition may be performed by using the mask frame assembly 100 will now be briefly described with reference to FIG. 6.

The mask frame assembly 100 may be used for depositing various thin films, for example, an emission layer pattern of an organic light-emitting display device.

FIG. 6 illustrates a structure of the organic light-emitting display device as an example of the target substrate 300 on which a thin film may be deposited by using the mask frame assembly 100 of an example embodiment.

Referring to FIG. 6, a buffer layer 330 is formed on a base plate 320, and a thin film transistor TFT is provided on the buffer layer 330.

The thin film transistor TFT includes an active layer 331, a gate insulating layer 332 covering the active layer 331, and a gate electrode 333 on the gate insulating layer 332.

An interlayer insulating layer 334 is formed to cover the gate electrode 333, and a source electrode 335a and a drain electrode 335b are formed on the interlayer insulating layer 334.

The source electrode 335a and the drain electrode 335b are respectively in contact with a source area and a drain area of the active layer 331 via contact holes formed in the gate insulating layer 332 and the interlayer insulating layer 334.

Furthermore, a pixel electrode 321 of an organic light emitting diode OLED is connected to the drain electrode 335b. The pixel electrode 321 is formed on a planarization layer 337, and a pixel defining layer 338 for diving sub-pixel areas is formed on the pixel electrode 321. Reference number 339 denotes a spacer for preventing members in the target substrate 300 from being damaged due to contact with the mask 120 by maintaining a gap between the mask 120 and the target substrate 300. The spacer 339 may be formed in a shape in which a portion of the pixel defining layer 338 protrudes. An emission layer 326 of the organic light emitting diode OLED is formed in an opening of the pixel defining layer 338, and an opposite electrode 327 is deposited on the emission layer 326 and the pixel defining layer 338. Thus, the opening surrounded by the pixel defining layer 338 is an area of a sub-pixel such as a red pixel R, a green pixel G, and a blue pixel B, and the emission layer 326 of the relevant color is formed in the opening covered with the pixel defining layer 338.

Accordingly, for example, when the mask 120 is prepared such that the pattern holes 121a correspond to the emission layer 326, the emission layer 326 having a desired pattern may be formed through the deposition process as described with reference to FIG. 1. The unit cell pattern 121b may correspond to a display area of an organic light-emitting display device.

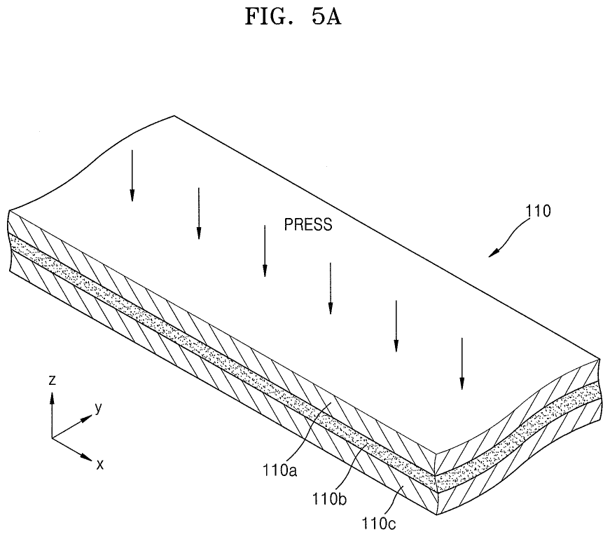

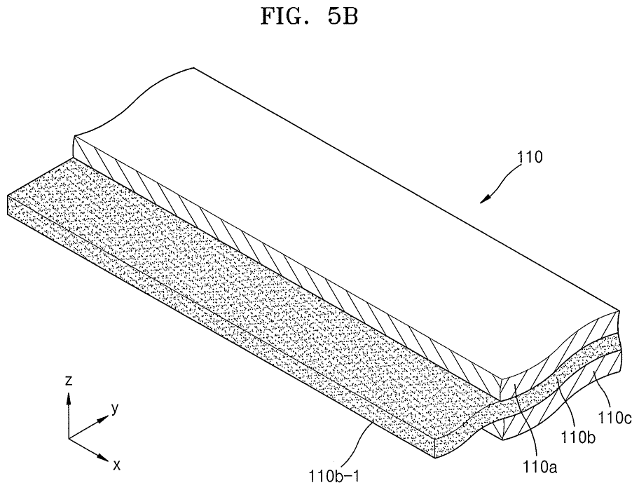

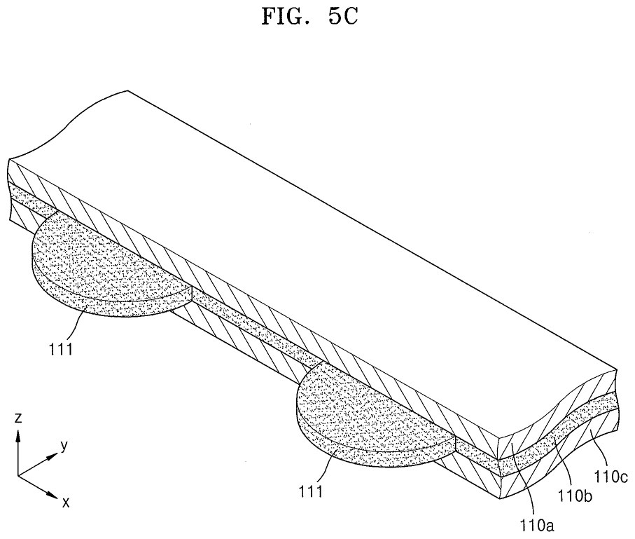

Hereinafter, a process of forming the mask frame assembly 100 for manufacturing the organic light-emitting display device as described above will be described with reference to FIGS. 2 and 5A through 5C. A process of manufacturing the long-side stick 110 having the clad structure described above will be described with reference FIGS. 5A through 5C, and a process of manufacturing the mask frame assembly 100 including the long-side stick 110 will be described with reference back to FIG. 2.

First, when manufacturing the long-side stick 110, as shown in FIG. 5A, the first layer 110a (which is the ferromagnetic layer and includes Invar), the second layer 110b (which is the weak magnetic layer and includes stainless steel, e.g., SUS304 (Fe:base, Cr:18.0˜22.0%, Ni:8.0˜10.5%, C:0.08%, Si:1.0%, Mn:2.0%, P:0.045%, S:0.03%)), and the third layer 110c (which is the ferromagnetic layer and includes Invar) are sequentially stacked and pressed, thus preparing a clad structure.

Next, the protrusion 111 above is formed at the second layer 110b. In detail, an end portion in a width direction (the Y direction) is removed from each of the first layer 110a and the third layer 110c by etching using photolithography, as shown in FIG. 5B. Thus, an end portion 110b-1 of the second layer 110b in the width direction (the y direction) is exposed outward.

Next, an etching process using photolithography is performed on the end portion 110b-1 of the second layer 110b that is exposed in the width direction (the Y direction), such that only the protrusion 111 remains. Thus, a structure in which a plurality of protrusions 111 are periodically arranged in the length direction (the X direction) is formed at the end portion of the second layer 110b in the width direction. Thus, the protrusion 111 is included in each of the unit cell patterns 121b in the above arrangement structure. Here, a case in which the protrusion 111 is semicircular is described, but the protrusion 111 may be formed into various shapes.

The long-side stick 110 formed in the above-described method is fixed to the frame 130 by, for example, welding as shown in FIG. 2, the mask 120 is alternately arranged on the long-side stick 110 and fixed by, for example, welding, and thus, the mask frame assembly 100 is manufactured.

By using the mask frame assembly 100 having the above-described structure, the force of the long-side stick 110 to bring the mask 120 into close contact with the target substrate 300 may be maintained at an adequate level that is neither excessively strong nor excessively weak. Accordingly, deposition defects such as an icicle defect or a shadow defect may be sufficiently controlled. Accordingly, stable quality of a product may be secured.

By way of summation and review, electrodes and an emission layer of an organic light-emitting display device may be formed by deposition. Thus, a mask having pattern holes identical to a target pattern of a thin film layer to be formed may be aligned on a substrate, and raw materials of a thin film layer may be deposited on the substrate through the pattern holes in the mask to form the thin film of the target pattern.

The mask may be used in the form of a mask frame assembly together with a frame for supporting edges of the mask and a long-side stick for dividing the pattern hole in a plurality of unit cell patterns. In a deposition operation, the mask is brought into close contact with the substrate due to magnetic force.

When the mask is brought into close contact with the substrate due to the magnetic force, the long-side stick is also drawn by the magnetic force, bringing the mask into close contact toward the substrate. Thus, in the deposition operation, a magnet, the substrate, the mask, and the long-side stick are sequentially arranged in an order. The mask and the long-side stick are drawn toward the substrate due to the magnetic force of the magnet, and the long-side stick further presses the mask toward the target substrate. On the other hand, if the long-side stick presses the mask toward the substrate with an excessively strong force, pattern holes formed in the mask may be deformed due to the pressing force of the long-side stick, and thus an icicle defect may occur in which a large gap is formed between the mask and the substrate and over-deposition occurs in the gap. If the long-side stick presses the mask toward the substrate with an excessively weak force, a gap may be formed between the mask and the substrate, and thus a shadow defect may occur in which deposition is performed beyond an intended periphery of a target deposition area. Thus, deposition defects may occur when the force for pressing the mask toward the substrate is excessively strong or excessively weak.

As described above, one or more embodiments include a mask frame assembly and a manufacturing method thereof, which are improved to maintain contact force applied to the mask by the long-side stick, at an adequate level that is neither excessively strong nor excessively weak.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A mask frame assembly, comprising:
a frame, a mask combined to the frame and including a pattern area for deposition on a substrate, and a long-side stick combined to the frame and dividing the pattern area of the mask into unit cell patterns,
wherein the long-side stick includes a clad structure in which a relatively ferromagnetic layer and a relatively weak magnetic layer are stacked.

2. The mask frame assembly as claimed in claim 1, wherein a thickness of the relatively ferromagnetic layer is greater than a thickness of the relatively weak magnetic layer in a stacking direction.

3. The mask frame assembly as claimed in claim 1, wherein a protrusion protruding in a width direction is located at the relatively weak magnetic layer.

4. The mask frame assembly as claimed in claim 3, wherein the protrusion corresponds to a non-emission pattern at a side of the unit cell pattern.

5. The mask frame assembly as claimed in claim 3, wherein the protrusion includes a semicircular shape.

6. The mask frame assembly as claimed in claim 3, wherein a plurality of the protrusions are periodically arranged in a length direction at an end portion of the relatively weak magnetic layer in a width direction.

7. The mask frame assembly as claimed in claim 1, wherein the clad structure includes a structure in which the relatively weak magnetic layer is located between a pair of the relatively ferromagnetic layers.

8. The mask frame assembly as claimed in claim 1, wherein the relatively ferromagnetic layer is an iron-nickel alloy layer, and the relatively weak magnetic layer is a stainless steel layer.

9. The mask frame assembly as claimed in claim 1, wherein the long-side stick brings the mask into close contact with the substrate when a magnetic force is applied to the long-side stick from a position opposite to the long-side stick, with the mask and the substrate therebetween.

10. The mask frame assembly as claimed in claim 9, wherein a contact force applied to the mask by the long-side stick is a combination of relatively strong attraction of the relatively ferromagnetic layer and relatively weak attraction of the relatively weak magnetic layer.

11. A method of manufacturing a mask frame assembly, the method comprising:
preparing a long-side stick having a clad structure in which a relatively ferromagnetic layer and a relatively weak magnetic layer are stacked;
fixing the long-side stick to a frame; and
fixing, to the frame, a mask having a pattern area to be divided by the long-side stick.

12. The method as claimed in claim 11, further comprising forming the relatively ferromagnetic layer of the long-side stick to have a thickness greater than a thickness of the relatively weak magnetic layer in a stacking direction.

13. The method as claimed in claim 11, further comprising forming, at the relatively weak magnetic layer, a protrusion protruding in a width direction.

14. The method as claimed in claim 13, wherein the protrusion corresponds to a non-emission pattern at a side of a unit cell pattern.

15. The method as claimed in claim 13, wherein the protrusion includes a semicircular shape.

16. The method as claimed in claim 13, further comprising periodically arranging a plurality of the protrusions in a length direction at an end portion of the relatively weak magnetic layer in a width direction.

17. The method as claimed in claim 11, wherein the clad structure has a structure in which the relatively weak magnetic layer is located between a pair of the relatively ferromagnetic layers.

18. The method as claimed in claim 11, wherein the relatively ferromagnetic layer is an iron-nickel alloy layer, and the relatively weak magnetic layer is a stainless steel layer.

19. The method as claimed in claim 11, wherein the long-side stick brings the mask into close contact with a substrate when a magnetic force is applied to the long-side stick from a position opposite to the long-side stick, with the mask and the substrate therebetween.

20. The method as claimed in claim 19, wherein a contact force applied to the mask by the long-side stick is a combination of relatively strong attraction of the relatively ferromagnetic layer and relatively weak attraction of the relatively weak magnetic layer.
